(19) United States
(12) Patent Application Publication
(10) Pub. No.: US 2015/0136596 A1
(43) Pub. Date: May 21, 2015

(54) MAGNETRON SPUTTERING DEVICE, MAGNETRON SPUTTERING METHOD, AND NON-TRANSITORY COMPUTER-READABLE STORAGE MEDIUM

(71) Applicant: TOKYO ELECTRON LIMITED, Tokyo (JP)

(72) Inventors: Kanto Nakamura, Nirasaki City (JP); Toru Kitada, Nirasaki City (JP); Atsushi Gomi, Nirasaki City (JP); Tetsuya Miyashita, Nirasaki City (JP)

(73) Assignee: Tokyo Electron Limited, Tokyo (JP)

(21) Appl. No.: 14/402,775

(22) PCT Filed: Apr. 11, 2013
(86) PCT No.: PCT/JP2013/002463

§ 371 Date: Nov. 21, 2014

(30) Foreign Application Priority Data
May 31, 2012 (JP) 2012-125494

(51) Int. Cl. H01J 37/34

(52) U.S. Cl. CPC H01J 37/3455; H01J 37/3405
USPC 204/298.16

(57) ABSTRACT

A magnetron sputtering apparatus includes a target disposed to face a substrate mounted on a mounting part in a vacuum vessel and a magnet arrangement assembly installed at a back side of the target and having an array of magnets, the magnetron sputtering apparatus including: a gas supply part configured to supply a plasma generation gas into the vacuum vessel; a rotary mechanism configured to rotate the mounting part; a power supply part configured to apply a voltage to the target; a moving mechanism configured to move the magnet arrangement assembly between a first region and a second region; and a control unit configured to output a control signal, such that an average moving speed of the magnet arrangement assembly is different between the first region and the second region.

### TECHNICAL FIELD

The present disclosure relates to a magnetron sputtering apparatus and a magnetron sputtering method for forming a film on a substrate, and a non-transitory computer-readable storage medium including a program for performing the method.

### BACKGROUND

A magnetron sputtering apparatus, which is an apparatus for forming a metal thin film in a semiconductor device, is provided with a target made of a metal, which is installed above a substrate, and a magnet installed at a back side of the target. In the area of a bottom surface of the target, a leakage magnetic field from the magnet causes a magnetic field to be formed in parallel with the bottom surface of the target. Then, if negative potential DC power or high frequency power, for example, is supplied to the target, an inert gas such argon (Ar) gas introduced into a vacuum vessel collides with electrons accelerated by an electric field to be ionized. The magnetic and electric fields cause the electrons generated by the ionization to drift generating high density plasma, and the argon ions in the plasma sputter the target to strike and emit metal particles.

Depending on an apparatus, the target may be disposed in parallel with a substrate or may be obliquely disposed with respect to a substrate. It has been known that in order to cause the entire surface of the target to erode, the magnet rotates or revolves. In addition, since the distribution of emission angles of sputtered particles from the target is different for each material of the target, the magnetron sputtering apparatus is generally provided with a height adjustment mechanism for elevating up and down a stage with respect to the target. By adjusting the height of the stage according to the material of the target, it is possible to prevent deterioration in the uniformity of film thickness distribution. The adjustment mechanism includes bellows to maintain an airtight seal between the vacuum vessel and the stage.

However, since the up-down movable distance of the stage is limited due to factors caused by components of the apparatus, such as an extensible range of the bellows, it cannot be absolutely true that the stage may be disposed at a proper position. Although it can be considered that the problem is dealt with by configuring the apparatus so as to increase the up-down movable distance of the stage, there are problems in that the cost of manufacturing the height adjustment mechanism would increase and the height of the vacuum vessel would become taller to thereby enlarge the apparatus. In addition, although the film thickness distribution can be controlled by adjusting a pressure when a film is formed (process pressure), there are some cases in which the problem cannot be solved by the pressure adjustment. That is, when suitable film quality, stress, film properties or the like are required for a thin film to be formed, such factors may be changed by the process pressure in some cases. Accordingly, when the process pressure for a film thickness distribution and the process pressure for the above factors are different from each other, there is a trade-off.

An example of a semiconductor device possibly having such a problem may include an MRAM (Magnetic Random Access Memory), which is expected as a memory element capable of solving problems of a conventional RAM. The MRAM is a memory element using a TMR (Tunnel Magnetic Resistance) element, in which an insulating film is interposed between magnetic films made of a ferromagnetic material and a resistance value of the element is varied depending on whether magnetization directions of the magnetic films are the same or opposite with each other. For the MRAM, appropriate magnetic properties for the magnetic films are required.

Since the magnetic properties of the magnetic films are varied according to the process pressure, when a pressure range for obtaining desired magnetic properties for the magnetic films and a pressure range for securing the film thickness uniformity are different from each other, the problem cannot be dealt with by only adjusting the process pressure. Although the film thickness distribution can be adjusted by the height of the stage as already described, when a height adjustable range is limited in view of the apparatus configuration, the stage cannot be disposed at an appropriate position in some cases. In addition, even if a wide range of height adjustments could be performed, the film thickness uniformity may be insufficient by solely relying on height adjustment.

### SUMMARY

The present disclosure has been made in consideration of the above points, and provides some embodiments of a technique capable of forming a film having high in-plane uniformity of a substrate by a magnetron sputtering method.

In one embodiment of the present disclosure, there is provided a magnetron sputtering apparatus including a target disposed to face a substrate mounted on a mounting part in a vacuum vessel and a magnet arrangement assembly installed at a back side of the target and having an array of magnets. The magnetron sputtering apparatus includes: a gas supply part configured to supply a plasma generation gas into the vacuum vessel; a rotary mechanism configured to rotate the mounting part; a power supply part configured to apply a voltage to the target; a moving mechanism configured to move the magnet arrangement assembly between a first region and a second region which is closer to an outer edge side of the target than the first region; and a control unit configured to output a control signal such that an average moving speed of the magnet arrangement assembly is different between the first region and the second region, wherein an entire area of an arrangement region of the magnet arrangement assembly is ⅔ or less of an area of the target.

Specific embodiments of the present disclosure are, for example, as follows: (a) The moving mechanism symmetrically moves the magnet arrangement assembly with respect to the central portion of the target; (b) The average moving speed of the magnet arrangement assembly at the first region is higher than the average moving speed of the magnet arrangement assembly at the second region; (c) The moving mechanism is configured to reciprocate the magnet arrangement assembly; (d) The moving mechanism is configured to circumferentially move the magnet arrangement assembly; and (e) The control unit includes a memory part configured to store moving patterns of the magnet arrangement assembly and corresponding processing types and outputs the control signal to move the magnet arrangement assembly based on a moving pattern corresponding to a processing type.

According to the present disclosure, in the case where a magnet arrangement assembly is moved between a first region and a second region which is closer to an outer edge side of a target than the first region, an average moving speed of the magnet arrangement assembly is different between the first region and the second region. Accordingly, a film can be formed on a rotating substrate with high uniformity.

### BRIEF DESCRIPTION OF THE DRAWINGS

FIG. 1 is a longitudinal sectional side view of a magnetron sputtering apparatus according to the present disclosure.

FIG. 2 is a perspective view of a magnet arrangement assembly, a target and a stage installed in the sputtering apparatus.

FIG. 3 is a bottom view of the magnet arrangement assembly.

FIG. 4 is a bottom view of another magnet arrangement assembly.

FIG. 5 is a plan view showing dimensions of the target and the magnet arrangement assembly.

FIG. 6 is a view illustrating a configuration of a control unit installed in the sputtering apparatus.

FIG. 7 is a graph illustrating a moving pattern of the magnet arrangement assembly.

FIG. 8 is a graph illustrating another moving pattern of the magnet arrangement assembly.

FIGS. 9 to 11 are views illustrating a state in which a film is formed by a sputtering method.

FIG. 12 is a plan view showing another moving pattern of the magnet arrangement assembly.

FIGS. 13 and 14 are plan views showing the moving pattern.

FIG. 15 is a perspective view illustrating another example of the configuration of the magnet arrangement assembly, the target and the stage.

FIG. 16 is a graph showing film thickness distributions obtained by simulations.

FIG. 17 is a graph showing moving patterns of the magnet arrangement assembly in multiple embodiments.

FIG. 18 is a graph showing sheet resistance distributions.

FIG. 19 is a graph showing moving patterns of the magnet arrangement assembly in multiple embodiments.

FIG. 20 is a graph showing film thickness distributions.

FIG. 21 is a graph showing sheet resistance distributions.

### DETAILED DESCRIPTION

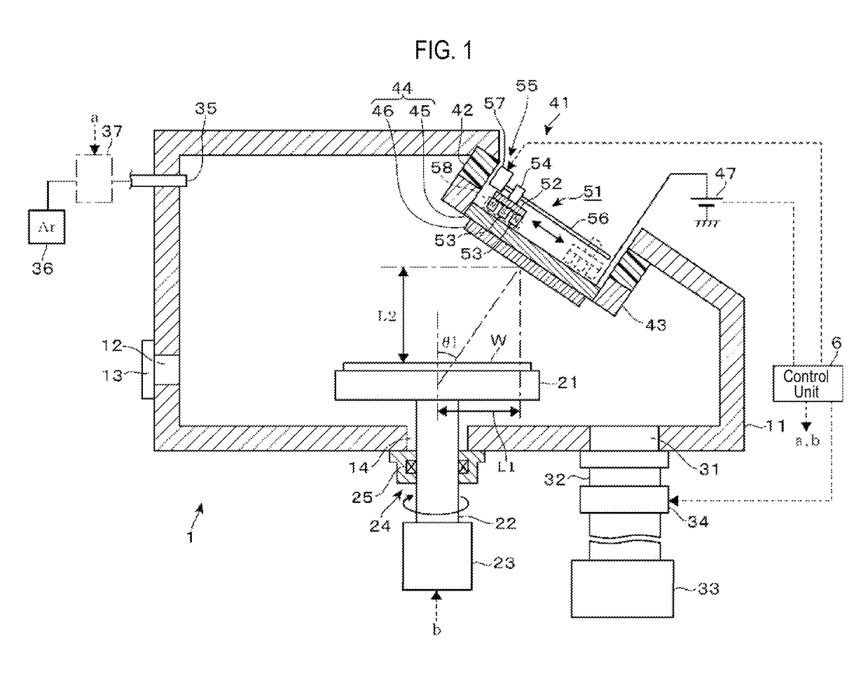

A magnetron sputtering apparatus 1 according to one embodiment of the present disclosure will be described with reference to the drawings. FIG. 1 is a longitudinal sectional side view of the magnetron sputtering apparatus 1. In the figure, reference numeral 11 designates a vacuum vessel, which is made of, for example, aluminum (Al), and is grounded. In the figure, reference numeral 12 designates a transfer port of a wafer W as a substrate, which is opened at a sidewall of the vacuum vessel 11 and is opened and closed by an opening/closing mechanism 13.

A circular stage 21 that is a mounting part is installed inside the vacuum vessel 11, and the wafer W is horizontally mounted on a surface of the stage 21. One end of a shaft part 22, which extends in the vertical direction, is connected to the central portion of the rear surface of the stage 21. The other end of the shaft part 22 extends outside of the vacuum vessel 11 through an opening 14 formed at a bottom portion of the vacuum vessel 11 and is connected to a rotary mechanism 23. The stage 21 is configured to be rotatable around the vertical axis by the rotary mechanism 23 via the shaft part 22. A cylindrical rotary seal 24 is installed around the shaft part 22 so as to block a gap between the vacuum vessel 11 and the shaft part 22 from outside of the vacuum vessel 11. In the figure, reference numeral 25 designates a bearing installed at the rotary seal.

A heater (not shown) is installed inside the stage 21, thereby heating the wafer W at a predetermined temperature in a film forming process. In addition, the stage 21 is provided with protruding pins (not shown) configured to transfer the wafer W between the stage 21 and an external transfer mechanism (not shown) of the vacuum vessel 11.

An exhaust port 31 is opened at a lower portion of the vacuum vessel 11. The exhaust port 31 is connected to one end of an exhaust pipe 32. The other end of the exhaust pipe 32 is connected to an exhaust pump 33. In the figure, reference numeral 34 designates an exhaust amount adjustment mechanism, which is installed through the exhaust pipe 32 to serve to adjust an internal pressure of the vacuum vessel 11. A gas nozzle 35, which is a plasma generation gas supply part, is installed at an upper side of the sidewall of the vacuum vessel 11. The gas nozzle 35 is connected to a gas supply source 36 in which an inert gas such as Ar is stored. In the figure, reference numeral 37 designates a flow rate adjustment part including a mass flow controller, which controls the amount of Ar gas being supplied to the gas nozzle 35 from the gas supply source 36.

A rectangular opening 41 is formed at a ceiling of the vacuum vessel 11. An insulating member 42 is installed along an edge of the opening 41 inside of the vacuum vessel 11. A holding part 43 is installed along the insulating member 42. A target electrode 44, which is rectangular-shaped in a plan view, is held in the internal periphery of the holding part 43 by the holding part 43 so as to block the opening 41. The target electrode 44 is insulated from the vacuum vessel 11 by the insulating member 42. The target electrode 44 is configured to be freely interchanged depending on the process.

The target electrode 44 consists of a conductive rectangular base plate 45 made of, e.g., Cu or Fe, and a target 46 constituting a film forming material. The target 46 is made of any one material of Co—Fe—B (cobalt-iron-boron) alloy, Co—Fe alloy, Fe, Ta (tantalum), Ru, Mg, IrMn, PtMn and the like, for example, for constituting a MRAM element. The target 46 is stacked and installed at the lower side of the base plate 45. Further, in this example, although a negative DC voltage is applied to the target electrode 44 by a power supply part 47, an AC voltage may be applied instead of the DC voltage.

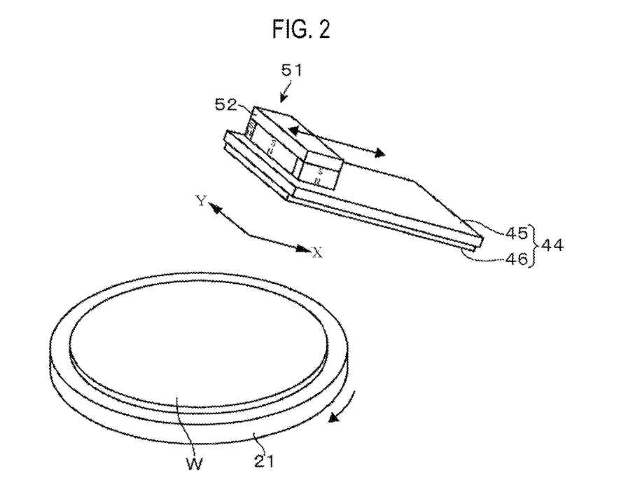

FIG. 2 is a perspective view of the target electrode 44. In this example, the target electrode 44 is obliquely disposed with respect to the wafer W on the stage 21 such that the short sides of the target electrode 44 are horizontal and the ends of one of the long sides of the target electrode 44 are disposed over an end of the wafer W. Thus, the center of the target 46 is positioned at an outer side from the center of the wafer W.

The target 46 that is disposed to be oblique and offset in the horizontal direction with respect to the wafer W is to deposit sputtered particles on the wafer W with high uniformity. When the target 46 is made of an alloy, it is possible to enhance alloy composition uniformity of the film formed on the wafer W. The sputtered particles from the target 46 are emitted according to the cosine law. That is, a number of the sputtered particles are emitted in proportion to the cosine value of an angle of the direction in which the sputtered particles are emitted with respect to a normal line of the surface of the target 46. As compared with a case where the target 46 is disposed horizontally or above the wafer W, it is possible to enlarge a region of the target 46 in which the sputtered particles can be emitted to the wafer W while suppressing an increase in the area of the target 46. However, when the present disclosure is embodied, the target 46 may be disposed horizontally or above the wafer W to overlap with an edge of the wafer W.

In FIG. 1, an angle θ1 between a normal line of the wafer W (a line in the thickness direction) and the central axis of the target 46 is set to fall within a range of, for example, 0 to 45 degrees. A distance L1 (referred to as an offset distance) in the horizontal direction between the center of the target 46 and the center of the wafer W on the stage 21 is set to fall within a range of, for example, 150 mm to 350 mm. A distance from the wafer W mounted on the stage 21 to the center of the target electrode 44 is a TS distance L2. The TS distance L2 is set to fall within a range of, for example, 150 mm to 350 mm.

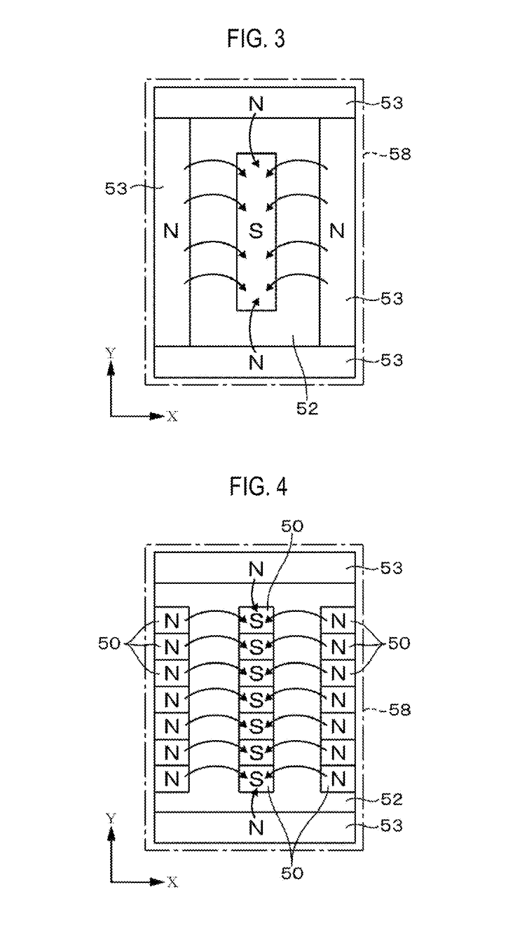

Subsequently, a magnet arrangement assembly 51 installed on top of the target electrode 44 will be described. In the description, a length direction of the target 46 is referred to as the X direction, and a width direction of the target 46 is referred to as the Y direction. The magnet arrangement assembly 51 includes a rectangular support plate 52 parallel with the target 46, and a plurality of magnets 53 constituting a magnetic circuit. One end of the magnets 53 is supported on the bottom surface of the support plate 52, and the other end of the magnets 53 is close to the target electrode 44. FIG. 3 shows the bottom surface of the support plate 52. Four magnets 53 extending along the four sides of the support plate 52 are arranged so as to surround the central portion of the support plate 52. In addition, one magnet 53 is installed to be spaced apart from the four magnets 53 such that the central portion of the support plate 52 extends in the Y direction. There is a difference in polarity between the target 46 sides of the magnets 53 installed along the aforementioned four sides and the target 46 side of the magnet 53 installed at the aforementioned central portion. The magnetic field lines generated by disposing the magnets 53 in such a manner are schematically shown by curved arrows in the figure. The configuration of the magnets shown in FIG. 3 is an example, and the present disclosure is not limited thereto. FIG. 4 shows another example configuration of the magnets 53. The configuration shown in FIG. 4 is different from the configuration shown in FIG. 3 in that a plurality of magnets 50 having a shorter Y direction length than the magnet 53 are disposed in the Y direction. There is another difference that the magnet groups including the plurality of magnets 50 disposed in the Y direction are spaced apart from the magnets 53 extending in the X direction.

As shown in FIG. 1, a bracket 54 is installed on top of the support plate 52. The bracket 54 is connected to a moving mechanism 55. The moving mechanism 55 is configured with a ball screw 56 extending, for example, in the X direction, and a motor 57 for rotating the ball screw 56 around its axis. As the ball screw 56 is threadedly coupled to the bracket 54 and the motor 57 rotates in normal and reverse directions, the magnet arrangement assembly 51 is moved in the X direction between one end side (upper end side) of the target 46 and the other end side (lower end side) thereof. Thus, it is possible to control an in-plane sputtered amount distribution of the target 46. Further, in order to suppress local sputtering of the target 46, the magnet arrangement assembly 51 is moved such that the traces drawn by the magnet arrangement assembly 51 seen from the one and the other end sides of the target 46 with respect to the center of the target 46 are symmetrical with each other. That is, the magnet arrangement assembly 51 is equidistantly moved from the center of the target 46 to the one and the other end sides, respectively.

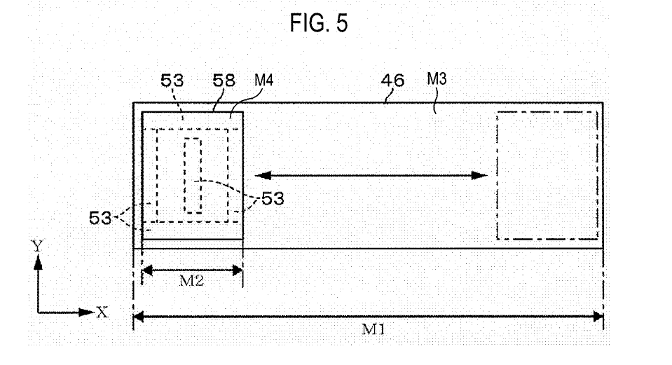

FIG. 5 is a plan view showing the target 46 and an arrangement region 58 of the magnets 53 at the support plate 52. A length of the target 46 in the X direction is M1 and a length of the arrangement region 58 in the X direction is M2. In order to perform the aforementioned movement, M2/M1 is set to be equal to or less than, for example, ⅔. In addition, the area of the target 46 is M3 and the area of the arrangement region 58 is M4. M4/M3 is set to be equal to or less than ⅔.

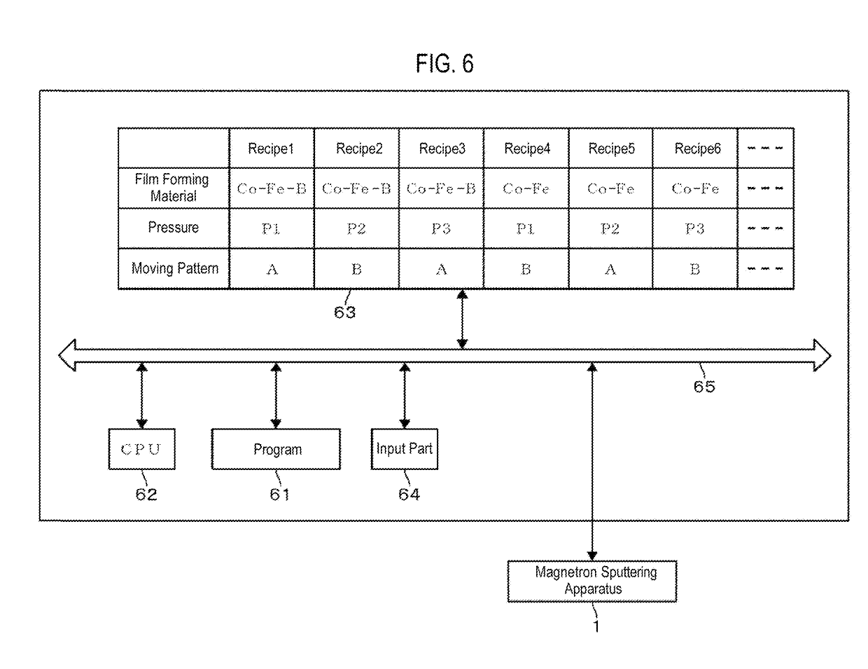

The magnetron sputtering apparatus 1 is provided with a control unit 6. FIG. 6 shows a configuration of the control unit 6. The control unit 6 includes a program 61, a CPU 62 configured to execute instructions of the program 61, a memory 63, and an input part 64. In the figure, reference numeral 65 designates a bus. The program 61 controls a power supply operation from the power supply part 47 to the target electrode 44, a flow rate adjustment of Ar gas by the flow rate adjustment part 37, a movement of the magnet arrangement assembly 51 by the moving mechanism 55, an internal pressure adjustment of the vacuum vessel 11 by the exhaust amount adjustment mechanism 34, a rotation of the stage 21 by the rotary mechanism 23, and the like. As described later, with this configuration, a group of steps is made so as to process the wafer W. The program 61 is stored in a storage medium, such as a hard disc, a compact disc, a magneto-optical disc, a memory card, or the like, and is installed to a computer from the storage medium.

The memory 63 stores materials of the target 46, internal pressures of the vacuum vessel 11 in a film forming process, and the types of moving patterns of the magnet arrangement assembly 51, and the numbers of processing recipes, which are recorded correspondingly to each other. The moving pattern will be described later. The input part 64 is configured with, for example, a mouse, a keyboard, a touch panel and the like. A user of the magnetron sputtering apparatus 1 selects a processing recipe number from the input part 64. By selecting the number, the operation of the exhaust amount adjustment mechanism 34 is controlled such that the internal pressure of the vacuum vessel 11 is set to a pressure corresponding to this processing recipe when the wafer W is processed. Then, a control signal is transmitted to the motor 57 such that the magnet arrangement assembly 51 is moved in a moving pattern corresponding to this processing recipe. As described above, for each film forming material, since stress or magnetic properties of a film are determined by the internal pressure of the vacuum vessel 11 in the processing, the user selects a processing recipe number corresponding to the pressure at which desired stress and magnetic properties are obtained. The setting of this processing recipe may be performed, for example, for each lot of the wafer W. The lot and the selected processing recipe correspond to each other and are stored in the memory 63.

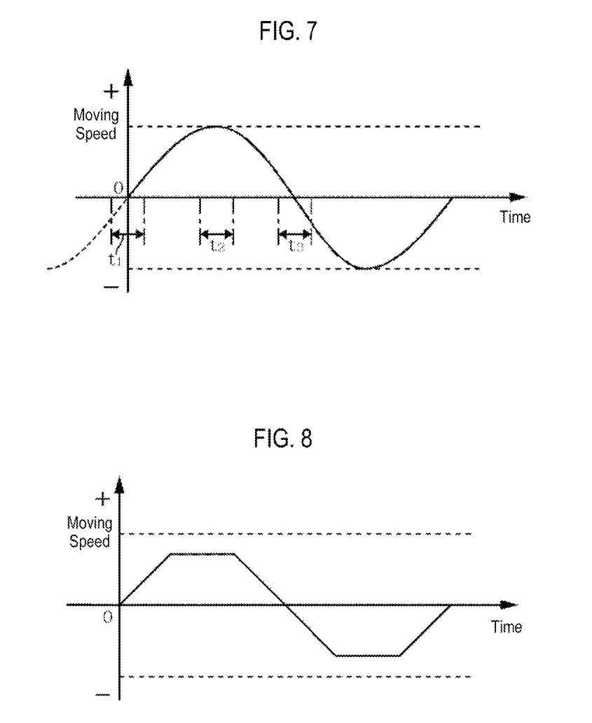

Subsequently, a moving pattern of the magnet arrangement assembly 51 will be described. As described above, the magnet arrangement assembly 51 is moved in the length direction of the target 46. In this example, the magnet arrangement assembly 51 is moved with one of a moving pattern A and a moving pattern B, in which their average moving speeds are different from each other at each portion of the target 46. FIGS. 7 and 8 show graphs of moving patterns when the magnet arrangement assembly 51 is moved on the target 46 one time. That is, when the magnet arrangement assembly 51 goes from one end side of the target 46 to the other end side and returns from the other end side to the one end side. The graph of FIG. 7 shows movement of the moving pattern A, and the graph of FIG. 8 shows movement of the moving pattern B. The vertical axis of each graph represents the moving speed of the magnet arrangement assembly 51, and the horizontal axis represents time. The speed is represented as being positive when the magnet arrangement assembly 51 moves from the one end side toward the other end side. The speed is represented as being negative in the graph when the magnet arrangement assembly 51 moves from the other end side toward the one end side, for convenience. When both the moving patterns A and B have a moving speed of zero (0), the magnet arrangement assembly 51 is positioned on the one end or the other end of the target 46.

The graph of the moving pattern A has a sine wave shape. In the moving pattern B, when the magnet arrangement assembly 51 moves from the one end side toward the other end side and from the other end side toward the one end side on the target 46, there is a period in which an absolute value of the moving speed is constant after being increased until the absolute value of the moving speed decreases. The constant speed is the maximum speed in the moving pattern B, which is lower than the maximum speed in the moving pattern A shown by dotted lines in the graph of FIG. 8. In these moving patterns A and B, the average moving speed when the magnet arrangement assembly 51 passes through the central portion (first region) of the target 46 is higher than the average moving speed when the magnet arrangement assembly 51 passes through both the ends (second regions) of the target 46.

There will be described a relationship between the average moving speed of the magnet arrangement assembly 51 and sputtered particles scattered from the target 46. A plasma density becomes higher in a section of the target 46 having a high magnetic field strength, and a sputtering rate in this section also becomes higher. In other words, a large number of sputtered particles are emitted from a section of the target 46 at which the magnet arrangement assembly 51 stays. Further, in a section of the target 46 at which the magnet arrangement assembly 51 stays for a long time, since a residence time of plasma is lengthened, the number of sputtered particles emitted is increased. That is, a sputtering rate is higher in a section of the target 46 at which the average moving speed of the magnet arrangement assembly 51 is lower. On the contrary, a sputtering rate is lower in a section at which the average moving speed of the magnet arrangement assembly 51 is higher.

The present disclosure requires that the average moving speed of the magnet arrangement assembly is different between the first region and the second region which is closer to an outer edge side of the target 46 than the first region. This means that a residence time of the magnet arrangement assembly 51 in the first region is different from a residence time in the second region. In addition, in the case where the average moving speed of the magnet arrangement assembly 51 in the first region is higher than the average moving speed of the magnet arrangement assembly 51 in the second region means that the residence time of the magnet arrangement assembly in the first region is shorter than the residence time of the magnet arrangement assembly 51 in the second region.

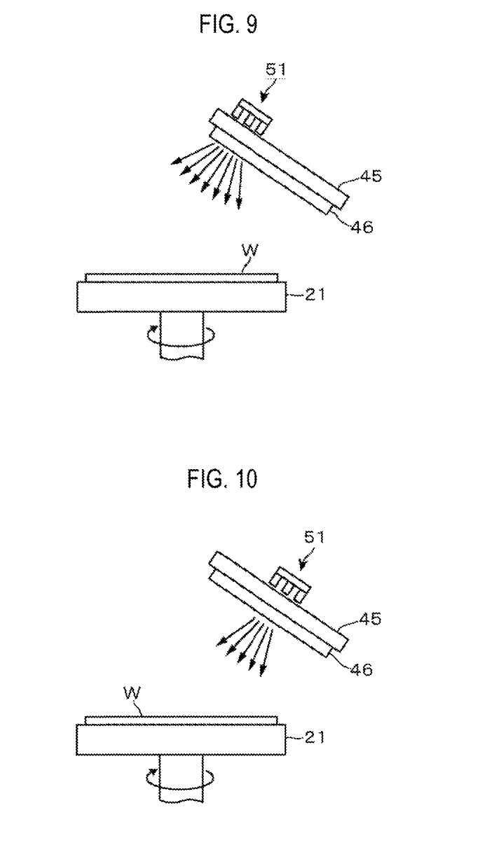

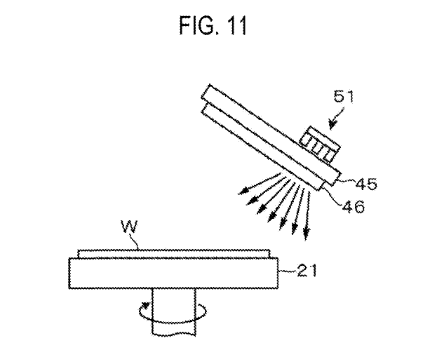

For the moving pattern A, FIGS. 9, 10, and 11 schematically show a state in which the target 46 is sputtered. FIGS. 9, 10, and 11 show the magnet arrangement assembly 51 in sections t1, t2 and t3 in the graph of FIG. 7, respectively. In the respective sections, the magnet arrangement assembly 51 moves over the one end, the central portion and the other end of the target 46, respectively. The respective sections t1 to t3 are equal to each other in size. FIGS. 9, 10, and 11 show that as the number of arrows becomes larger, a sputtering rate of the target 46 becomes higher. As described above, a difference in the average moving speed of the magnet arrangement assembly 51 causes a sputtering rate at the central portion of the target 46 to be lower than a sputtering rate at and one of the other ends of the target 46.

Since the average moving speed of the magnet arrangement assembly 51 at the central portion of the target 46 in the moving pattern B is lower than that in the moving pattern A, the sputtering rate at the central portion in the moving pattern B is higher than that in the moving pattern A. As shown in simulations described later, a film thickness distribution of the wafer W can be controlled by selecting the moving pattern A or B.

Depending on an internal pressure of the vacuum vessel 11 and a material of the target 46, a direction in which sputtered particles are emitted from the target 46 is changed. Accordingly, when the magnet arrangement assembly 51 is moved in the same moving pattern for each processing recipe, the film thickness distribution is varied. In order to keep the variation in film thickness distribution caused by the pressure or the material of the target 46 even and obtain a highly uniform film thickness distribution moving pattern A or B are determined for each processing recipe and stored in the memory 63.

Subsequently, the operation of the above-described magnetron sputtering apparatus 1 will be described. A user of the magnetron sputtering apparatus 1 determines a processing recipe for each lot of the wafer W loaded in the magnetron sputtering apparatus 1 according to a material of the target 46 disposed inside the vacuum vessel 11 and a desired pressure when a film forming process is performed. Then, the user inputs the determined processing recipe number through the input part 64 for each lot. Thereafter, the transfer port 12 of the vacuum vessel 11 is opened. The wafer W is loaded onto the stage 21 by cooperation between the external transfer mechanism (not shown) and push-up pins. Subsequently, the transfer port 12 is closed, the Ar gas is supplied into the vacuum vessel 11, and the exhaust amount is controlled by the exhaust amount adjustment mechanism 34. Thus, the interior of the vacuum vessel 11 is maintained at the pressure designated in the processing recipe of the wafer W.

Then, while the stage 21 is rotated around the vertical axis, the magnets 53 are moved over the target 46 in the moving pattern of the determined processing recipe along the length direction of the target 46 by the moving mechanism 55. In addition, as a negative DC voltage is applied to the target electrode 44 from the power supply part 47, an electric field is generated around the target electrode 44. Then, electrons accelerated by the electric field collide with the Ar gas, thereby ionizing the Ar gas. As the Ar gas is ionized, new electrons are generated. In addition, the magnets 53 generate a magnetic field along the surface of the target 46 in which the magnets 53 are positioned.

Furthermore, the magnetic field and the electric field in the vicinity of the target 46 accelerate the electrons which will drift. Then, the electrons having sufficient energy caused by the acceleration also collide with the Ar gas and cause ionization of the Ar gas. Thus, plasma is generated, and Ar ions in the plasma sputter the target 46. In addition, secondary electrons generated by the sputtering are captured by the horizontal magnetic field and those captured electrons contribute to the ionization again. Thus, an electron density is increased to generate high density plasma. At this time, the magnet arrangement assembly 51 is moved on a back side of the target 46 in the determined moving pattern A or B. As described above, for the moving pattern B, since the average moving speed of the magnet arrangement assembly 51 at the central portion in a length direction of the target 46 is lower as compared to that for the moving pattern A, a residence time of plasma at the central portion is lengthened to increase the sputtering rate of the target 46.

By changing a gradient of the sputtering rate in the plane of the target 46 as described above, the number of the sputtered particles incident on a periphery of the wafer W can be adjusted. As the wafer W is rotated, a position on which the sputtered particles are incident deviates to a periphery of the wafer W, so that a film is formed on the wafer W with high uniformity.

If the power supply part 47 is turned on and then a predetermined amount of time passes, the power is turned off to stop generation of plasma and supply of the Ar gas, the vacuum vessel 11 is exhausted by a predetermined exhaust amount, and the wafer W is unloaded from the vacuum vessel 11 as in the reverse operation of loading the wafer W. Then, the succeeding wafer W is processed in the same manner as the previous wafer W. Then, if the lot of the wafer W transferred to the magnetron sputtering apparatus 1 is changed, the magnet arrangement assembly 51 is moved in the moving pattern determined for the corresponding lot. In addition, when the target electrode 44 is replaced and a material of the target 46 is changed, the user selects a processing recipe according to the changed target 46 and the pressure and performs the process.

According to the magnetron sputtering apparatus 1, during a film-forming process, the magnet arrangement assembly 51 is moved between the one and the other end sides of the target 46 over the target 46, which is obliquely installed with respect to the rotating stage 21, with a varying average moving speed. With this configuration, a distribution of sputtered amount of the target 46 can be controlled to form a film with high in-plane uniformity of the wafer W. In addition, depending on the pressure and material of the target 46 in a film-forming process, the moving pattern of the magnet arrangement assembly 51 is determined. Accordingly, a film thickness having higher in-plane uniformity can be formed on the wafer W.

For example, a lifting mechanism for the stage 21 may be installed to the rotary mechanism 23 in order to adjust the TS distance L2, and a film thickness distribution may be controlled by changing the TS distance according to the processing recipe, such that the in-plane film thickness uniformity of the wafer W may be enhanced. When the lifting mechanism is installed in this way, since the film thickness distribution can be controlled by moving the magnet arrangement assembly 51 as described above, it is possible to prevent the necessary movable distance for lifting from being increased. Accordingly, regardless of whether or not the lifting mechanism is installed, it becomes possible to suppress the manufacturing cost of the apparatus and to prevent the apparatus from being enlarged.

While in the above example, the sputtering rate at both the ends of the target 46 is higher than the sputtering rate at the central portion, the present disclosure is not limited to such a control. For example, the average moving speed of the magnet arrangement assembly 51 at the central portion of the target 46 may be lower than the average moving speed at both the ends, such that the sputtering rate of both the ends may be lower than the sputtering rate of the central portion. For this reason, when the magnet arrangement assembly 51 moves from one end of the target 46 to the other, for example, the magnet arrangement assembly 51 may be momentarily stopped at the central portion of the target 46.

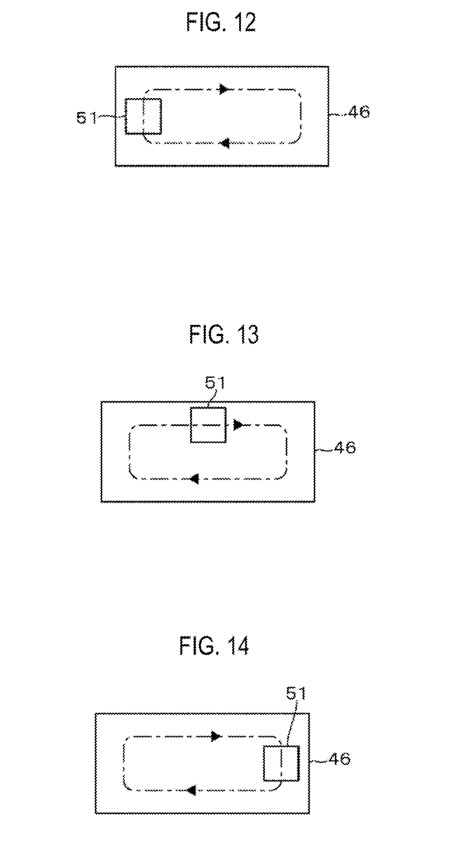

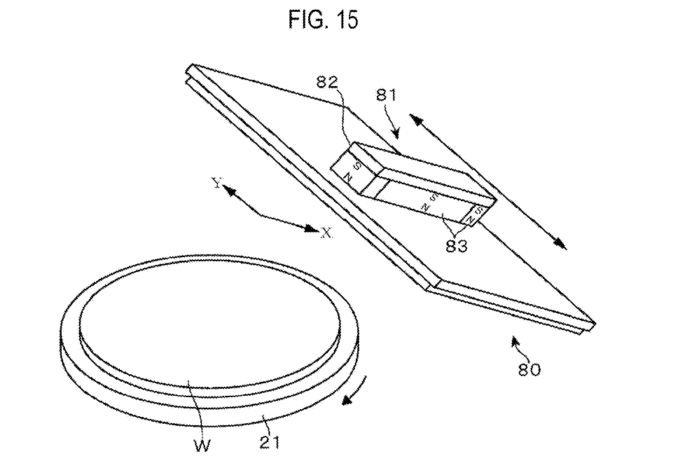

The moving pattern of the magnet arrangement assembly 51 by the moving mechanism 55 is not limited. For example, FIGS. 12, 13 and 14 show another moving pattern. In this example, the magnet arrangement assembly 51 is circumferentially moved along the sides of the target 46 as viewed from the top, such that the trace thereof is represented by chain line arrows in the figures. Even in such circumferential movement, the magnet arrangement assembly 51 is moved according to the moving pattern shown in FIGS. 7 and 8 in the same manner as when being moved back. That is, the average moving speed when the magnet arrangement assembly 51 is moved at both the ends of the target 46 is lower than the average moving speed when it is moved at the central portion. FIGS. 12, 13 and 14 show positions of the magnet arrangement assembly 51 at predetermined time points within the sections t1, t2 and t3, respectively, when the magnet arrangement assembly 51 is moved in the moving pattern A. In addition, even when the magnet arrangement assembly 51 is circumferentially moved in this way, the average moving speed when the magnet arrangement assembly 51 is moved at both the ends of the target 46 may be also allowed to be lower than the average moving speed when it is moved at the central portion.

In the meantime, a shape of the target 46 is not limited to a rectangle, and the target 46 may be in the shape of an ellipse or an elongated circle, or a polygon other than a quadrangle. In addition, the moving pattern is not limited to two types. For example, a moving pattern C may be prepared in which the speed when the target 46 is moved at the central portion is lower than the case of the moving pattern B. Then, a moving pattern to be performed may be selected from the moving patterns A, B and C according to the processing recipe. Further, in this example, while the moving pattern is changed depending on the pressure and the material of the target 46 that are processing parameters in a processing recipe, an angle of the sputtered particles emitted from the target 46 is also changed depending on the voltage applied to the target 46 as a processing parameter. Accordingly, the moving pattern may be changed based on this processing parameter.

However, in this example, the magnet arrangement assembly 51 is moved so that the one and the other end sides of the target 46 are symmetrical with respect to the central portion of the target 46. With this configuration, the sputtered amount in the one and the other end is uniform. Thus, this prevents an uneven distribution of erosion and forming a film having high in-plane uniformity of a film thickness distribution of the wafer W, which falls in the scope of the present disclosure without departing from this technical spirit. For example, when the magnet arrangement assembly 51 is moved, even though the moving distance of the magnet arrangement assembly 51 from the central portion of the target 46 to the one end side is different from the moving distance from the central portion to the other end side by several millimeters or so, this does not depart from the technical spirit but falls within the symmetrical movement.

In addition, for example, when the magnet arrangement assembly 51 is moved, the magnet arrangement assembly 51 is moved 50 mm from the central portion of the target 46 to the one end side and 40 mm from the central portion of the target 46 to the other end side. Subsequently, the magnet arrangement assembly 51 is moved 40 mm to the one end side and 50 mm to the other end side. Such a movement is repeated. In this moving pattern, if the magnet arrangement assembly 51 is moved once in the route of the central portion of the target 46→the one end side→the other end side→the central portion, only the n-th (n is an integer number) movement does not make the magnet arrangement assembly 51 be symmetrically moved. For this reason, a difference in the sputtered amount occurs between the one and the other end sides, but the n+1-th reciprocation causes this difference to be canceled. That is, in the long term, the magnet arrangement assembly 51 is symmetrically moved in the same path with respect to each end. Even such a moving pattern falls within the scope of the present disclosure. In addition, the magnet arrangement assembly 51 is moved 50 mm to the one end and 50 mm to the other end. Subsequently, the magnet arrangement assembly 51 is moved 40 mm to the one end and 40 mm to the other end. Such a movement may be repeated. Even for such a moving pattern, since the magnet arrangement assembly 51 is symmetrically moved in the same path with respect to each end, the same effects are obtained.

In addition, another embodiment may be configured such that a magnet arrangement assembly 81 is moved over a target 80 in the horizontal direction. FIG. 15 shows this embodiment. In this embodiment, the target 80 is obliquely disposed above the wafer W such that the long sides of the target 80 are horizontal and the ends of the short sides of the target 80 adjacent to the center of the wafer W are above the outside ends of the short sides. In addition, the target 80 is positioned such that the normal line of the target 80 at the central portion (the line perpendicular to the bottom surface of the target 80) intersects the center line of the wafer W at the lower side of the wafer W. Further, the magnet arrangement assembly 81 has the same configuration as the magnet arrangement assembly 51 shown in FIGS. 1 to 3. In the figures, one end of magnets 83 is supported by the support plate 82 at a bottom surface of the support plate 82 and the other end of the magnets 83 is close to the target 80. Accordingly, such an arrangement is obtained by rotating the target 46 and the magnet arrangement assembly 51 of the magnetron sputtering apparatus 1 shown in FIGS. 1 and 2 90 degrees around the normal line passing through the center of the target 46. Further, although a moving mechanism is omitted in the figures, for example, the moving mechanism may be configured with a ball screw extending in the length direction (Y direction) of the target 80 in FIG. 15 and a motor, such that the magnet arrangement assembly 81 is moved between each end in the length direction of the target 80. Therefore, the magnet arrangement assembly 81 can be horizontally moved in the Y direction while being in parallel with the target 80.

The moving pattern in the embodiment shown in FIG. 1 may be applied to the moving pattern of the magnet arrangement assembly 81 in the embodiment shown in FIG. 15. In such a case, the positive and negative sides of the vertical axis of the moving pattern shown in FIGS. 7 and 8 are substituted with each end in the Y direction shown in FIG. 15, respectively. That is, the magnet arrangement assembly 81 of the embodiment shown in FIG. 12 is moved, for example, in the above-mentioned moving pattern A or B, between each end in the horizontal direction of the target 80.

### EMBODIMENTS

In order to evaluate the present disclosure, a moving pattern of the magnet arrangement assembly was set, and a film thickness distribution of a film formed on a wafer W when the firm was formed was obtained by simulations (Embodiment 1) and verification tests (Embodiments 2 to 4). In the simulations and the verification tests, the apparatus shown in FIG. 15 was assumed or used, and the values of the angle θ1, the offset distance L1, and the TS distance L2 were selected from the specific example ranges described in the first embodiment.

### Embodiment 1

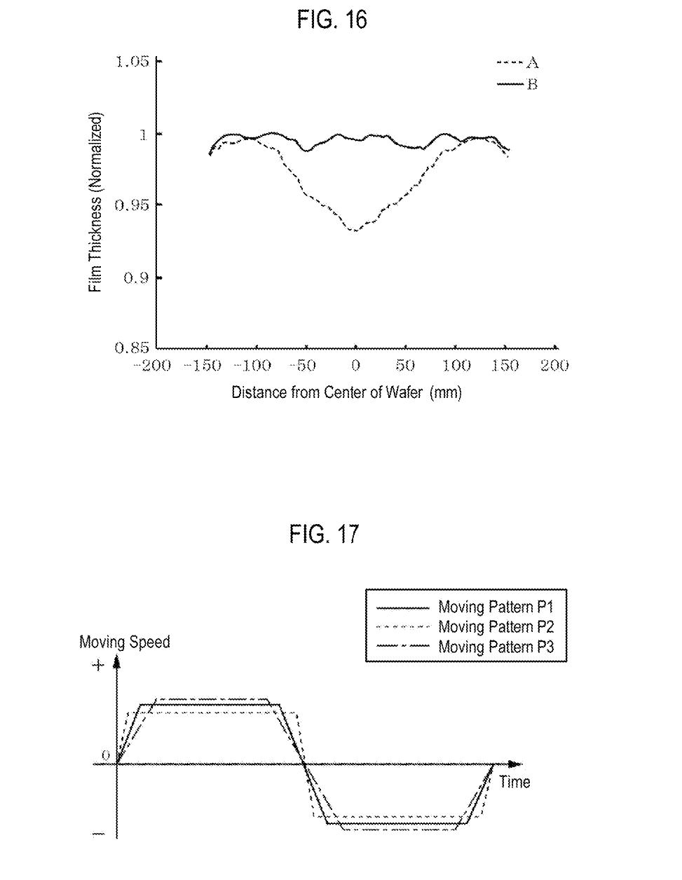

The simulations in the case where films were formed in the moving patterns A and B shown in FIGS. 7 and 8 were performed, respectively. The graph of FIG. 16 shows a film thickness distribution of the wafer W when the film was formed according to each moving pattern. In the graph, a dotted line represents the film thickness distribution when the processing was performed according to the moving pattern A and a solid line represents the film thickness distribution when the processing was performed according to the moving pattern B. The vertical axis of the graph is normalized such that a value of predetermined film thickness is one, and the horizontal axis represents the distance from the center of the wafer W. As a result of the film thickness distribution simulation, a film thickness distribution ((difference between maximum film thickness and minimum film thickness)/(average film thickness)) was 7.1% for the moving pattern A, whereas it was 2.3% for the moving pattern B.

As shown in the graph, as compared with the film formed according to the moving pattern A, the film formed according to the moving pattern B had a larger film thickness in the vicinity of the central portion of the wafer W. This is because, since the average moving speed of the magnet arrangement assembly 81 at the central portion of the target 80 was low, the sputtering rate of the central portion was increased and the number of the sputtered particles deposited in the vicinity of the central portion of the wafer W was increased. The simulations show that a film thickness distribution is changed by changing the moving pattern of the magnet arrangement assembly 81.

### Embodiment 2

A film thickness distribution of a film formed on the wafer W was confirmed, when two parameters, i.e., a time at which acceleration or deceleration was performed and a set speed in moving at a constant speed, were changed in the moving pattern set to move at the constant speed during a certain time zone, such as the moving pattern B. In addition, Ta was used as the material of the target 80.

FIG. 17 is a graph showing moving patterns P1 to P3 of the magnet arrangement assembly 81. The vertical axis of the graph represents the moving speed of the magnet arrangement assembly 81 and the horizontal axis represents time. The acceleration or deceleration time and the constant speed are assigned to each moving pattern, respectively.

Moving Pattern P1: Acceleration or Deceleration Time 249 msec, Constant Speed 112 mm/sec

Moving Pattern P2: Acceleration or Deceleration Time 99 msec, Constant Speed 103 mm/sec

Moving Pattern P3: Acceleration or Deceleration Time 369 msec, Constant Speed 120 mm/sec

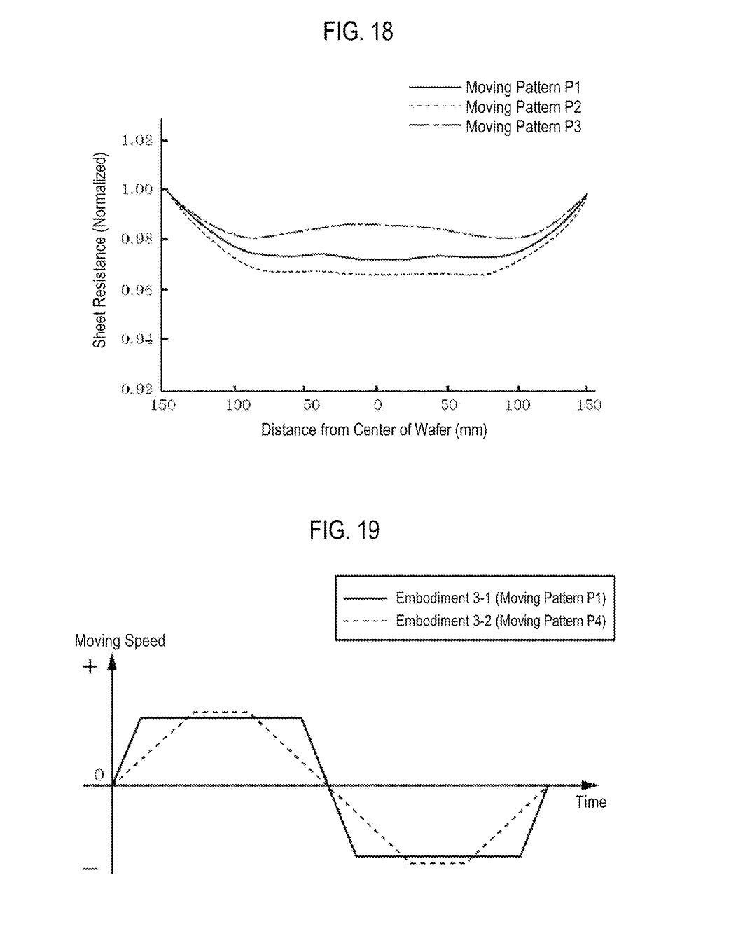

The graph of FIG. 18 shows sheet resistance distributions of films formed on wafers W when the films were formed according to the moving patterns P1 to P3, respectively. The vertical axis of the graph is normalized such that a value of predetermined sheet film thickness is one, and the horizontal axis represents the distance from the center of the wafer W. In addition, as a result of forming films according to the moving patterns P1 to P3, a sheet resistance distribution ((difference between maximum sheet resistance and minimum sheet resistance)/(average sheet resistance)) was 2.8% for the moving pattern P1, 3.5% for the moving pattern P2, and 2.0% for the moving pattern P3.

As shown in the graph of FIG. 18, the sheet resistance in the vicinity of the central portion of the wafer W is the largest when the film is formed according to the moving pattern P3 and the smallest when the film is formed according to the moving pattern P2. A result of the tests shows that a sheet resistance distribution is changed by adjusting the time of performing the acceleration or deceleration of the moving pattern of the magnet arrangement assembly 81 or the set speed in moving at a constant speed.

### Embodiment 3

Verification tests were performed to obtain a favorable film thickness distribution by adjusting the moving pattern even when the material of the target 80 was changed. In Embodiment 3-1, Ta was used as the material of the target 80, and a film was formed according to the moving pattern P1. In Embodiment 3-2, 70CoFe was used as the material of the target 80, and a film was formed according to the moving pattern P4 (acceleration or deceleration time 759 msec, constant speed 120 mm/sec). FIG. 19 is a graph showing the moving patterns P1 and P4 of the magnet arrangement assembly 81. The vertical axis of the graph represents the moving speed of the magnet arrangement assembly 81, and the horizontal axis represents time. The acceleration or deceleration time and the constant speed are assigned to each moving pattern, respectively.

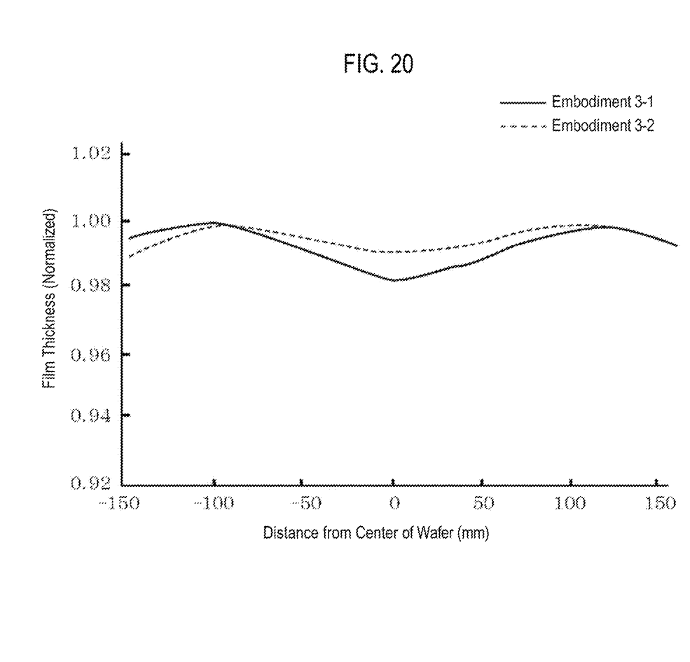

The graph of FIG. 20 shows film thickness distributions of films formed on wafers W when the films were formed according to Embodiments 3-1 and 3-2, respectively. The vertical axis of the graph is normalized such that a value of predetermined sheet film thickness is one, and the horizontal axis represents the distance from the center of the wafer W. According to both Embodiments 3-1 and 3-2, flat films having high uniformity were formed. In addition, a low film thickness distribution ((difference between maximum film thickness and minimum film thickness)/(average film thickness)) was obtained as 1.9% in Embodiment 3-1 and 1.6% in Embodiment 3-2. This test result shows that even when the material of the target 80 is changed, the film having a uniform film thickness is formed by adjusting the moving pattern of the magnet arrangement assembly 81.

### Embodiment 4

When the magnet arrangement assembly 81 is reciprocated, a pattern, in which the magnet arrangement assembly 81 is moved, e.g., α mm from the central portion of the target 80 to the one end side and α mm to the other end side and, then, β mm, other than α mm, to the one end side and β mm to the other end side, is set as one cycle. Verification tests for films formed by repeating the cycle were performed. In Embodiment 4, the magnet arrangement assembly 81 was moved 98 mm from the central portion of the target 80 to the one end side and 98 mm to the other end side and, then, 88 mm to the one end side and 88 mm to the other end side, and this cycle was repeated. In addition, Comparative Embodiment 4, in which a film was formed by repeatedly moving the magnet arrangement assembly 81 equidistantly, 98 mm, to both the end sides of the target 80, was performed. Further, PtMn was used as the material of the target 80.

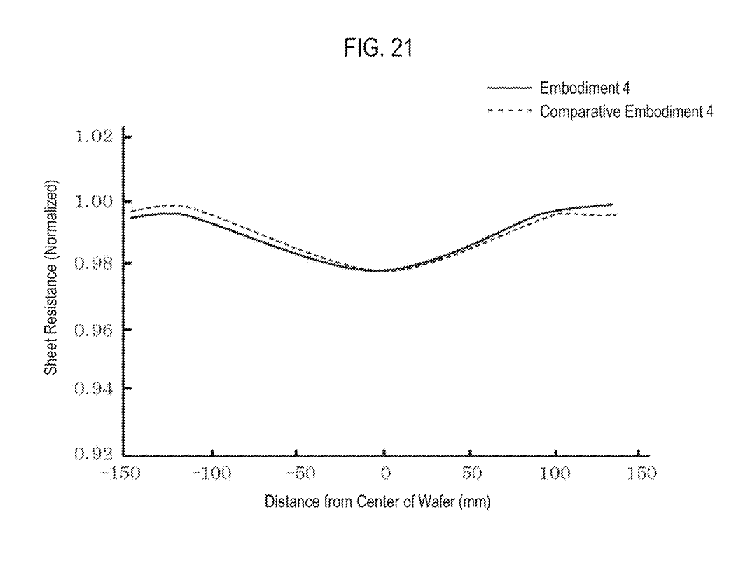

The graph of FIG. 21 shows sheet resistance distributions of films formed on wafers W when the films are formed according to Embodiment 4 and Comparative Embodiment 4, respectively. The vertical axis of the graph is normalized such that a value of predetermined sheet resistance is one, and the horizontal axis represents the distance from the center of the wafer W. In both Embodiment 4 and Comparative Embodiment 4, flat films were formed, and approximately similar sheet resistance profiles were obtained. Further, sheet resistance distribution ((difference between maximum sheet resistance and minimum sheet resistance)/(average sheet resistance)) was also 2.0% for both Embodiment 4 and Comparative Embodiment 4.

1. A magnetron sputtering apparatus including a target disposed to face a substrate mounted on a mounting part in a vacuum vessel and a magnet arrangement assembly installed at a back side of the target and having an array of magnets, the magnetron sputtering apparatus comprising:
a gas supply part configured to supply a plasma generation gas into the vacuum vessel;
a rotary mechanism configured to rotate the mounting part;
a power supply part configured to apply a voltage to the target;
a moving mechanism configured to move the magnet arrangement assembly between a first region and a second region which is closer to an outer edge side of the target than the first region; and
a control unit configured to output a control signal such that an average moving speed of the magnet arrangement assembly is different between the first region and the second region,
wherein an entire area of an arrangement region of the magnet arrangement assembly is ⅔ or less of an area of the target.

2. The magnetron sputtering apparatus of claim 1, wherein the moving mechanism symmetrically moves the magnet arrangement assembly with respect to the central portion of the target.

3. The magnetron sputtering apparatus of claim 1, wherein the average moving speed of the magnet arrangement assembly in the first region is higher than the average moving speed of the magnet arrangement assembly in the second region.

4. The magnetron sputtering apparatus of claim 1, wherein the moving mechanism is configured to reciprocate the magnet arrangement assembly.

5. The magnetron sputtering apparatus of claim 1, wherein the moving mechanism is configured to circumferentially move the magnet arrangement assembly.

6. The magnetron sputtering apparatus of claim 1, wherein the control unit includes a memory part configured to store moving patterns of the magnet arrangement assembly and corresponding processing types and outputs the control signal to move the magnet arrangement assembly based on the moving pattern corresponding to the processing type.

7. A magnetron sputtering method using a magnetron sputtering apparatus including a target disposed to face a substrate mounted on a mounting part in a vacuum vessel and a magnet arrangement assembly installed at a back side of the target and having an array of magnets, the magnetron sputtering method comprising:
rotating the mounting part;
applying a voltage to the target;
supplying a plasma generation gas into the vacuum vessel; and
moving the magnet arrangement assembly between a first region and a second region which is closer to an outer edge side of the target than the first region, such that an average moving speed of the magnet arrangement assembly is different between the first region and the second region,
wherein an entire area of an arrangement region of the magnet arrangement assembly is ⅔ or less of an area of the target.

8. The magnetron sputtering method of claim 7, wherein moving the magnet arrangement assembly comprises moving the magnet arrangement assembly to be symmetrical with respect to the central portion of the target.

9. The magnetron sputtering method of claim 7, wherein the average moving speed of the magnet arrangement assembly at the first region is higher than the average moving speed of the magnet arrangement assembly at the second region.

10. A non-transitory computer-readable storage medium configured to store a computer program used in a magnetron sputtering apparatus including a target disposed to face a substrate mounted on a mounting part in a vacuum vessel and a magnet arrangement assembly installed at a back side of the target and having an array of magnets,
wherein the computer program includes a group of steps for performing the magnetron sputtering method according to claim 7.
